(19) United States
(12) Patent Application Publication
(10) Pub. No.: US 2004/0211958 A1
(43) Pub. Date: Oct. 28, 2004

(54) Semiconductor device having a conductive layer and a manufacturing method thereof

(75) Inventors: Hideki Osamura, Oita-ken (JP); Mari Otsuka, Oita-ken (JP); Tadashi Matsuno, Oita-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/682,902

(22) Filed: Oct. 14, 2003

(30) Foreign Application Priority Data
Apr. 24, 2003 (JP) 2003-119506

(51) Int. Cl. H01L 23/58

(52) U.S. Cl. 257/48; 257/506

(57) ABSTRACT

A semiconductor device having a conductive layer comprising: a semiconductor substrate; a first interlayer insulating film formed above the semiconductor substrate; a first conductive layer formed in the first interlayer insulating film; a second interlayer insulating film formed on the first interlayer insulating film and the first conductive film; a contact that is formed in the second interlayer insulating film, an one end of the contact being electrically connected to the first conductive layer; a second conductive layer formed on the second interlayer insulting film and the contact; and a dummy pattern formed in the first conductive layer and adjacent to the one end of the contact, an upper surface of the dummy pattern reaching a lower surface of the second interlayer insulating film that is formed on the first conductive layer, and the lower surface of the dummy pattern reaching the first interlayer insulating film that is formed under the first conductive layer.

### CROSS-REFERENCE TO RELATED APPLICATION

This application is based upon and claims the benefit of priority from the prior Japanese Patent Application No. 2003-119506, filed Apr. 24, 2003, the entire contents of which are incorporated herein by reference.

### BACKGROUND OF THE INVENTION

1. Field of the Invention

This present invention relates to a semiconductor device with a damascene structure of a via contact and a manufacturing method thereof.

2. Description of the Related Art

Conventionally, a damascene structure is used for a via contact of a semiconductor device. There are advantages in that 1) it is easier to manufacture a semiconductor device with the damascene structure, and 2) in case of manufacturing the semiconductor device with the damascene structure, a RIE (Reactive Ion Etching) method that is difficult to form microscopic patterns of metal layers is not needed.

We will explain a conventional cupper electrode that is manufactured by the damascene technique. FIG. 8a shows a cross sectional view of an exemplary cupper electrode that is manufactured by the damascene technique. FIG. 8b shows a top view at a D-D′ depicted in FIG. 8a.

As shown in FIGS. 8a and 8b, a silicon oxide layer 2 is formed on a silicon substrate 1. An interlayer insulating film 3 is formed on the silicon layer 2. A barrier metal layer 4, for instance, a TaN layer/a Ta layer/a Cu layer (hereinafter, the Cu layer may be called as a seed layer) is formed in the groove formed in the interlayer insulating film 3. And then, a cupper electrode pattern 6 is formed on the barrier metal layer 4 and in the groove. An interlayer insulating film 7 is formed on the cupper electrode pattern 6. A groove 6 corresponding to a position of the cupper electrode pattern 6 is then formed in the interlayer insulating film 7. It is noted that, in this case, a diameter of the groove 5 is wider than that of a via contact hole 5a (a bottom portion of the groove 5). When we microscopically look at a state of cupper contained in the cupper electrode pattern 6, each of cupper grains 10 is formed to be close to a grain boundary. There are some vacancies on the grain boundary. In a result, voids occur on the grain boundary.

FIGS. 9a and 10a show cross sectional views of a manufacturing method of the electrode pattern. FIGS. 9b and 10b show top views thereof. Same reference numbers will be assigned to same portions shown in FIGS. 8a and 8b, and the explanation will be omitted.

As shown in FIGS. 9a and 9b, a silicon oxide layer 2 and an interlayer insulating film 3 are formed on a semiconductor substrate 1. And then, an electrode pattern groove 14 in which an electrode pattern 6 is to be formed is formed in the silicon layer 2. A barrier metal layer 4, for instance, a TaN layer/a Ta layer/a Cu layer, are formed in the electrode pattern groove 14, and then a cupper layer is formed in the electrode pattern groove 14 by using a plating method. After that, a portion of the cupper layer is removed by using a CMP (Chemical Mechanical etching) method, thereby leaving a portion of the cupper layer 6 in the electrode pattern groove 14. At this situation, when we microscopically take a look at a situation of the cupper contained in the electrode pattern 6, cupper grains 10 are formed to be close to a grain boundary 11. At this time, vacancies 12 are formed, but small yet.

As shown in FIGS. 10a and 10b, an interlayer insulating film 7 is formed on the interlayer insulating film 3 and the electrode pattern 6. At this situation, the cupper grains 10 are growing and the vacancies 12 are also expanding.

After forming the interlayer insulating film 7, as shown in FIGS. 8a and 8b, in case where the groove 5 and the via contact hole 5a are formed in the interlayer insulating film 7 so as to reach an upper surface of the electrode pattern 6, the vacancies 12 in the cupper of the electrode pattern 6 gather under the groove 5 and the voids occur on the grain boundary.

FIG. 11 shows exemplary top views of the electrode pattern 6 in case where a width of the electrode pattern 6 is changed and greater, assuming that a length t of the electrode pattern 6 is constant.

FIG. 12 shows an exemplary diagram of a width of the electrode pattern 6 under the via contact vs. a via resistance of the electrode pattern 6. The resistance of the electrode pattern 6 is measured by a four node method. As understood from FIG. 12, the wider the electrode pattern under the via contact becomes, the grater the resistance of the via contact becomes.

As shown in FIG. 10a, when the interlayer insulating film 7 is formed on the interlayer insulating film 3 depicted in FIG. 9, heat is added to the electrode pattern 6 containing cupper. In a result, a growth of the cupper grains 10 can be promoted, and the vacancies 12 on the grain boundaries 11 can be spread. Specifically, it is easy to the vacancies 12 in the grain boundaries 11 gather, thereby making the voids on the grain boundaries 11.

As shown in FIGS. 8a and 8b, after the groove 5 and the via contact hole 5a are formed, that is, after heat process is performed, the vacancies 12 within about 10 micro meters from a bottom portion of the via contact hole 5a tend to come together at the bottom portion of the via contact hole 5a. Thereby, very big voids are formed at the bottom portion of the via contact hole 5a. Because at the bottom portion of the via contact hole 5a, a stress of the interlayer insulating film 7 is smaller. From this, via open defects may occur, and a resistance of the via contact may become higher.

And also, as shown in FIG. 12, when a resistance of the via contact is measured by the four node method, we found that the wider the electrode pattern under the via contact becomes, the grater the resistance of the via contact becomes. This result shows that voids tend to occur at the bottom portion of the groove 5 (a bottom portion of the via contact 5a). Inversely, the narrower the electrode pattern under the via contact becomes, the smaller the resistance of the via contact becomes, thereby resulting in preventing the voids from occurring and in becoming a lower resistance of the via contact.

It should be noted that it is not preferable to make a width of the electrode pattern narrower technically. Because an area at which the electrode pattern is contact with the via contact is smaller, thereby resulting in lower reliability and stability of an electrical signal transmission.

### SUMMARY OF INVENTION

A first aspect of the present invention is a semiconductor device having a conductive layer comprising: a semiconductor substrate; a first interlayer insulating film formed above the semiconductor substrate; a first conductive layer formed in the first interlayer insulating film; a second interlayer insulating film formed on the first interlayer insulating film and the first conductive film; a contact that is formed in the second interlayer insulating film, an one end of the contact being electrically connected to the first conductive layer; a second conductive layer formed on the second interlayer insulting film and the contact; and a dummy pattern formed in the first conductive layer and adjacent to the one end of the contact, an upper surface of the dummy pattern reaching a lower surface of the second interlayer insulating film that is formed on the first conductive layer, and the lower surface of the dummy pattern reaching the first interlayer insulating film that is formed under the first conductive layer.

A second aspect of the present invention is providing a semiconductor device having a conductive layer comprising: a semiconductor substrate; a first interlayer insulating film formed above the semiconductor substrate; a first conductive layer formed in the first interlayer insulating film; a second interlayer insulating film formed on the first interlayer insulating film and the first conductive layer; and a contact that is formed in the second interlayer insulating film, an one end of the contact being electrically connected to the first conductive layer; wherein portions of the first interlayer insulting film are extending into the first conductive layer, the portions of the first interlayer insulting film are adjacent to the end of the contact.

A third aspect of the present invention is providing A method for manufacturing a semiconductor device having a conductive layer, comprising: forming a first interlayer insulting film above a semiconductor substrate; forming a groove in the first interlayer insulting film by removing a predetermined portion of the first interlayer insulating film in an electrode region at which an electrode is to be formed, and leaving a portion other than the predetermined portion of the first interlayer insulating film in the electrode region; forming a conductive layer in the groove; forming a second interlayer insulating film on the first interlayer insulating film and the conductive layer; and forming a contact in the second interlayer insulating film so as to reach an upper surface of the conductive layer, the upper surface of the conductive layer being adjacent to the portion other than the predetermined portion of the first interlayer insulating film.

### BRIEF DESCRIPTION OF THE DRAWINGS

FIG. 1 shows a cross sectional view and a top view of an embodiment in the present invention. Specifically, FIG. 1a shows the cross sectional view after a step of forming a contact hole. And FIG. 1b shows the top view in case that an interlayer insulating film 7 would be ignored.

FIGS. 2a to 2e show manufacturing steps of the embodiment in the present invention.

FIG. 3 shows a cross sectional view and a top view of the embodiment in the present invention. Specifically, FIG. 3a shows the cross sectional view after a step of forming a photo resist layer 13. And FIG. 3b shows the top view in case that the photo resist layer 13 would be ignored.

FIG. 4 shows a cross sectional view and a top view of the embodiment in the present invention. Specifically, FIG. 4a shows the cross sectional view after a step of forming a photo resist layer 13a. And FIG. 4b shows the top view in case that the photo resist layer 13a would be ignored.

FIG. 5 shows a top view depicts dummy pattern of the embodiment in the present invention.

FIG. 6 shows a measurement data depicts a distance between a via contact and a dummy pattern vs. a via resistance of the embodiment in the present invention.

FIG. 7 shows a measurement data depicts a width of a line under a via contact vs. a via resistance of the embodiment in the present invention.

FIG. 8 shows a cross sectional view and a top view of a conventional semiconductor device. Specifically, FIG. 8a shows the cross sectional view after a step of forming an interlayer insulating film 7. And FIG. 8 b shows the top view in case that the interlayer insulating film 7 would be ignored.

FIG. 9 shows a cross sectional view and a top view of a conventional semiconductor device. Specifically, FIG. 9 a shows the cross sectional view after a step of forming an electrode 6. And FIG. 9 b shows the top view thereof.

FIG. 10 shows a cross sectional view and a top view of a conventional semiconductor device. Specifically, FIG. 10a shows the cross sectional view after a step of forming an interlayer insulating film 7. And FIG. 10b shows the top view in case that the interlayer insulating film 7 would be ignored.

FIG. 11 shows electrodes with a variety of widths thereof in case that length of the electrode is constant.

FIG. 12 shows a measurement data depicts a width of a line under a via contact vs. resistance thereof.

### DETAILED DESCRIPTION OF THE INVENTION

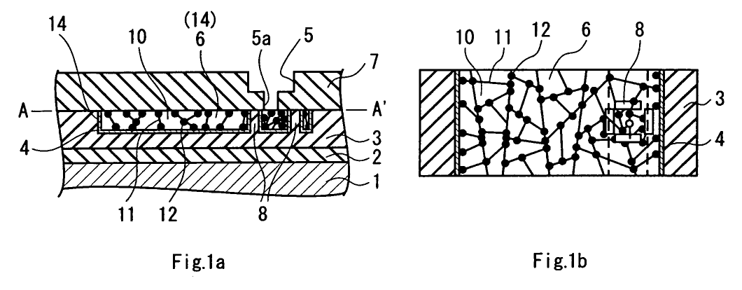

FIG. 1 shows a cross sectional view and a top view of an embodiment in the present invention. Specifically, FIG. 1a shows the cross sectional view after a step of forming a contact hole 5. And FIG. 1b shows the top view in case that an interlayer insulating film 7 would be ignored.

As shown in FIGS. 1a and 1b, a semiconductor layer 2 is formed on a silicon substrate 1. An interlayer insulating film 3 is formed on the semiconductor layer 2. A groove 14 in which an electrode is to be formed is formed in an upper surface of the interlayer insulating film 3. An electrode layer 6 that is made of cupper is formed in the groove 14 via a barrier metal layer 4, for instance, a TaN layer/a Ta layer/a cupper layer (hereinafter, the cupper layer may be called as a seed layer). A width of the electrode layer 6 is greater than a diameter of a bottom portion of a groove 5. An interlayer insulating film 7 is formed on the electrode layer 6 and the interlayer insulating film 3. The groove 5 corresponding to the electrode layer 6 is formed in the interlayer insulating film 7.

As shown in FIG. 1a, a bottom portion of the groove 5 is a via contact hole 5a. Hereinafter, a term of the “groove” can be used as including a via contact hole 5a. A dummy pattern 8 that is four insulating films is located so as to surround the via contact hole 5a within 10 micro meters from the bottom portion of the via contact hole 5a. And also, one of the four insulating films is apart from the others, and any two insulating films adjacent to each other are apart by a predetermined distance. A cross sectional view of any four insulating films is almost square.

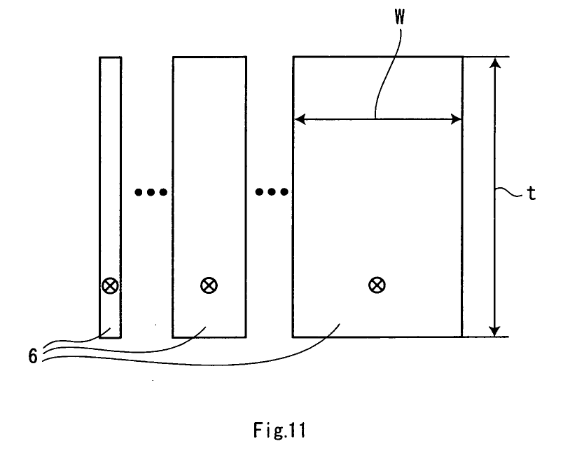

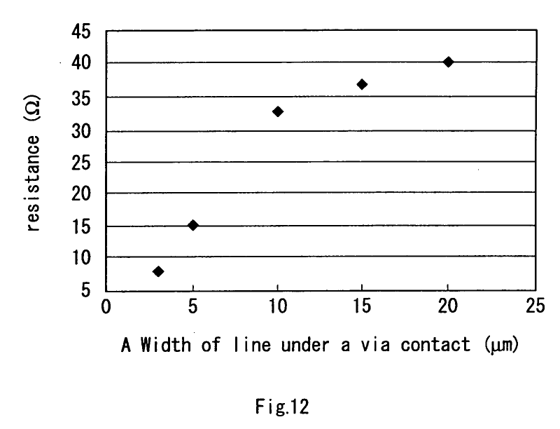

The dummy pattern 8 is provided, thereby avoiding an occurrence of voids in the electrode pattern 6 and making a contact resistance lower. Because, as understood by observing microscopically the electrode pattern 6 (See FIG. 10), the vacancies 12 that occurred at the grain boundary 11 tend to get together toward the dummy pattern 8 and the vacancies 12 do not tend to gather under the groove 5.

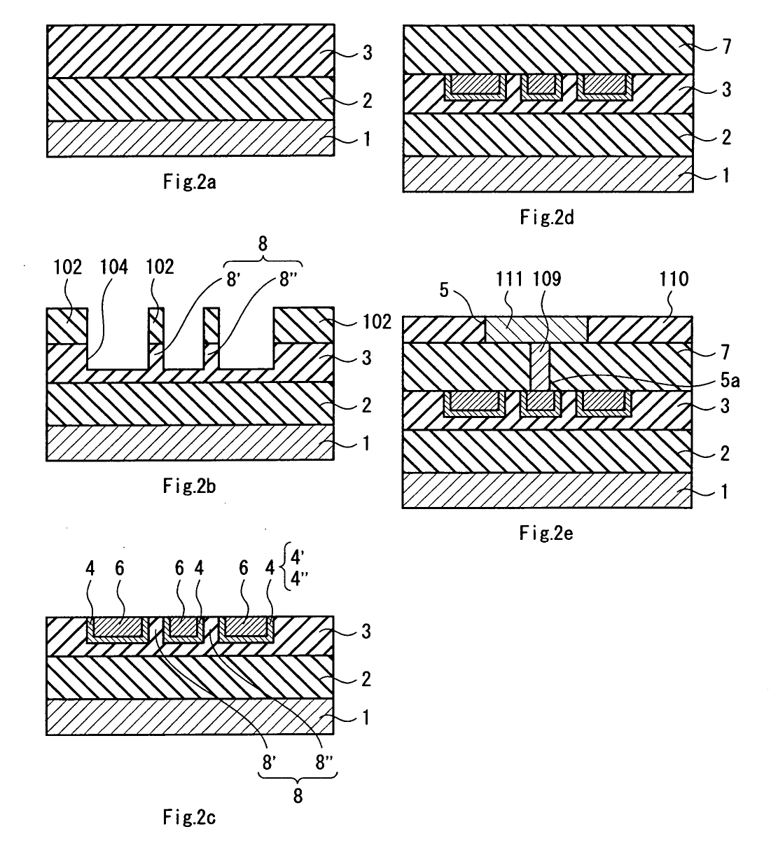

We will explain manufacturing steps of an embodiment of the present invention with reference to FIGS. 2, 3, and 4.

FIG. 2 shows the manufacturing steps of an embodiment of the present invention. As shown in FIG. 2a, a semiconductor layer 2 is formed on a silicon substrate 1. An interlayer insulating film 3 is then formed on the semiconductor layer 2.

As shown in FIG. 2b, by using i-ray of mercury lamp, KrF excimer laser, and ArF excimer laser, a photo resist layer 102 with a predetermined pattern is formed on the interlayer insulating film 3. By using a dry etching method and the photo resist layer 102 with the predetermined parttern as a mask, a groove 104 in which an electrode pattern is to be formed is formed in the interlayer insulating film 3. At the same time, project portions 8′ and 8″ (hereinafter, called as dummy pattern 8) are formed.

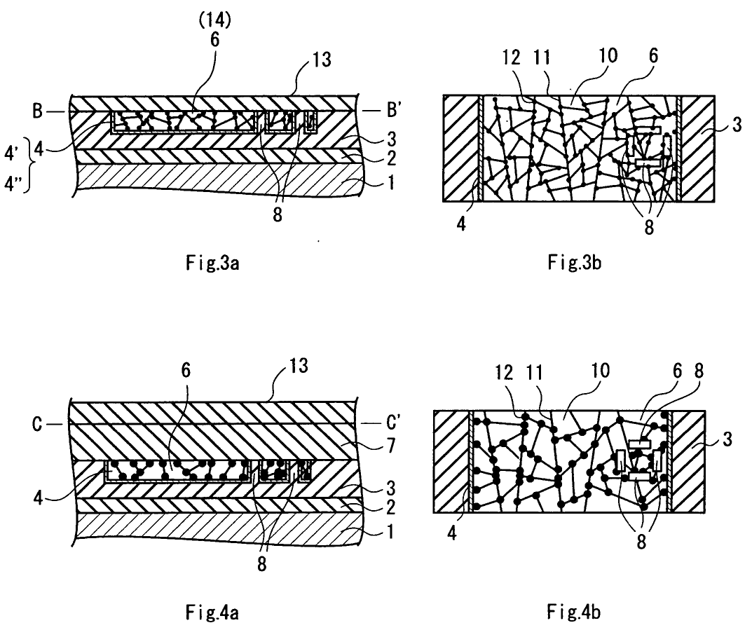

It should be noted that, the dummy pattern 8 comprises four portions (See FIG. 1). Each of four portions is located from an opening portion of a groove 5 (not shown in FIG. 2b) within 10 micrometers. One of the four portions is apart from the others, and any two portions adjacent to each other are apart by a predetermined distance. The four portions are located to surround the opening portion of the groove 5a in almost square (See FIG. 3b).

As shown in FIG. 2c, a barrier metal layer 4, for instance, a TaN layer/a Ta layer/a cupper layer (the cupper layer is called as a seed layer) is formed in the groove 104 and on side surfaces of the dummy pattern 8 by using a sputtering method. The patterned resist layer 102 with the predetermined pattern is then removed by using an ashing method. A Cu layer 6 is formed in the groove 104 and on the barrier metal layer 4 by using a plate method and a CMP (Chemical Mechanical Polishing) method.

FIG. 3 shows a state of the Cu layer 6 before an interlayer insulating film 7 is formed, that is, a heat step is performed. As shown in FIG. 3, the vacancies 12 in the Cu layer 6 are still small.

As shown in FIG. 2d, the interlayer insulating film 7 is formed on the interlayer insulating film 3, the Cu layer 6, and the barrier metal layer 4 by using a CVD (Chemical Vapor Deposition) method. It should be noted that heat is added to all layers including the Cu layer 6 when the interlayer insulating film 7 is formed.

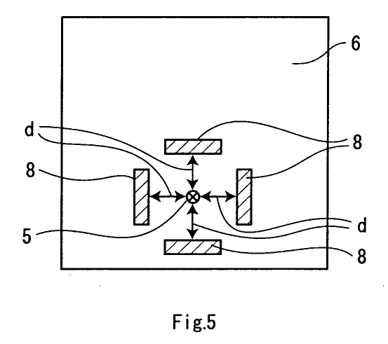

FIG. 4 shows a state of the Cu layer 6 after the interlayer insulating film 7 is formed, that is, a heat step is performed. As shown in FIG. 4, the vacancies 12 in the Cu layer 6 become bigger. However, the vacancies 12 within a region where the dummy pattern 8 is surrounding do not become bigger. Because the dummy pattern 8 prevents a grain growth within the region where the dummy pattern 8 is surrounding from becoming bigger. Thereby, an occurrence of the voids that is almost formed in a wide pattern, for instance, a wide metal line is also prevented.

As shown in FIG. 2e, an interlayer insulating film 110 is formed on the interlayer insulating film 7. A photo resist layer (not shown) with a predetermined pattern is then formed on the interlayer insulating film 110. By using and an etching method and the photo resist layer with a predetermined pattern as a mask, the contact holes 5 and 5a are formed in the interlayer insulating films 110 and 7 respectively. The photo resist layer is then removed by using an ashing method. After that, the conductive contact 109 and a conductive layer 111 are formed in the contact holes 5 and 5a respectively. For simplicity, following steps to be performed will be omitted.

We will explain arrangement of the dummy pattern 8 in the bottom portion of the contact hole 5a with reference to FIG. 5. As shown in FIG. 5, the dummy pattern 8 may be located from the bottom portion of the contact hole 5a (opening portion) by a distance d which is 20 micrometers or less.

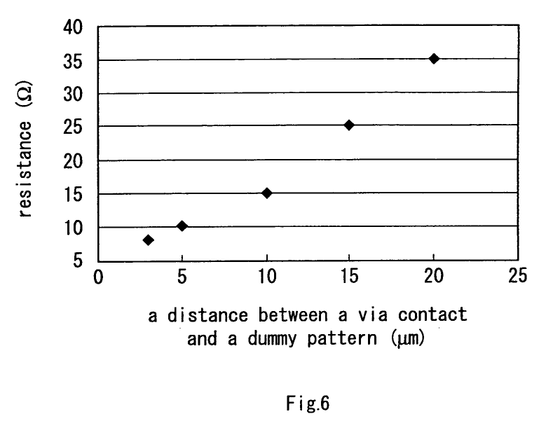

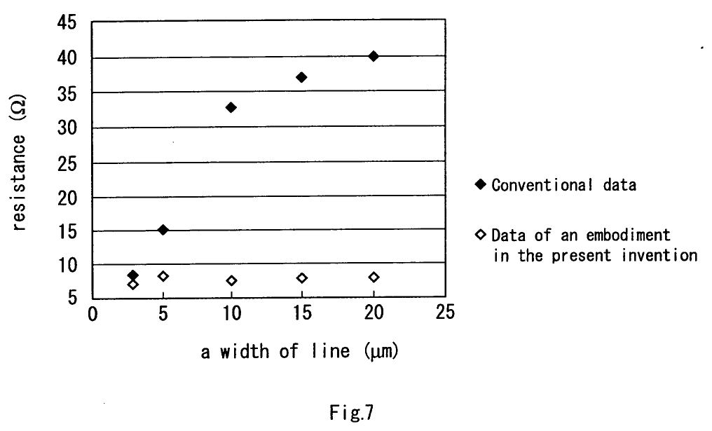

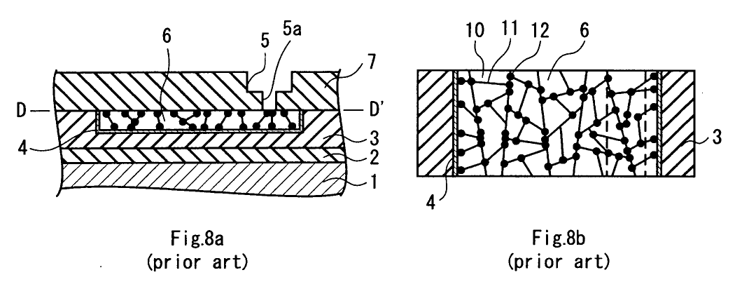

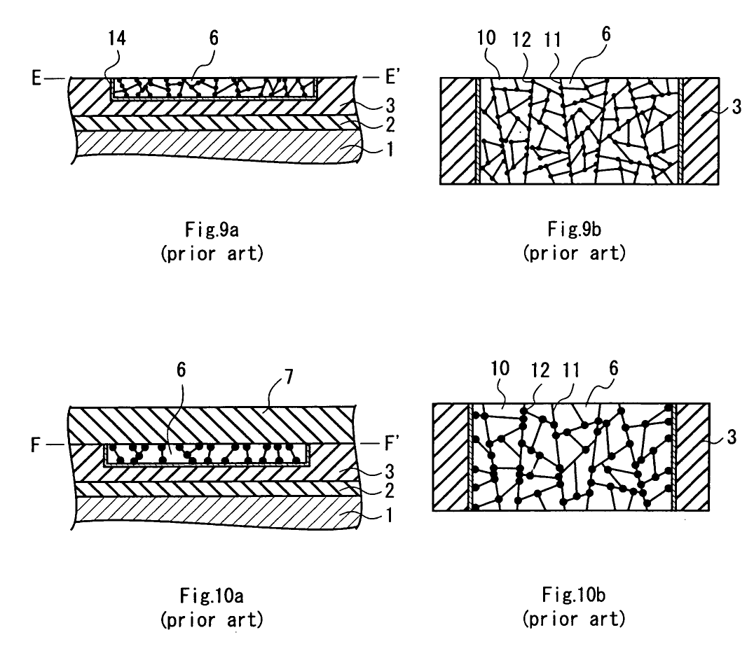

FIG. 6 shows a measurement data that depicts the distance d between the bottom portion of the contact hole 5a (opening portion) and the dummy pattern 8 vs. a via resistance of the embodiment in the present invention. The data is measured by using a four node method. As understood from this result, the distance d between the bottom portion of the contact hole 5a (opening portion) and the dummy pattern 8 should be within 10 micrometers in order that a via resistance is 15 ohm or less.

And also, FIG. 7 shows measurement data that depicts a width of a line under a via contact vs. a via resistance of the conventional technique and the embodiment of the present invention. As shown in FIG. 7, in case where the width of the line is 20 micrometers or less, the via resistance of the embodiment in the present invention is 10 ohm or less. On the other hand, in case where the width of the line is 5 micrometers or more, the via resistance of the conventional technique is increasing. From this result, the embodiment of the present invention allows the via resistance to prevent from increasing.

As explained above, the dummy pattern 8 comprises four projecting portions of the interlayer insulating film 3, and the location of the four projecting portions is almost square. However, the embodiment in the present invention should not be limited thereto. The dummy pattern 8 may have a single projecting portion or a number of the projecting portion other than four. And also, the location of the projecting portion(s) may be almost a circle, a triangle, or a polygonal location. Of course, a combination thereof, for instance, 1) the single projecting portion and the circle location, 2) the single projecting portion and the triangle location, 3) the single projecting portion and the polygonal location, 4) the five projecting portions and the triangle location, and so on would be allowed.

The semiconductor device of the embodiment in the present invention may be formed on a semiconductor substrate on which at least one of a dynamic DRAM device, a nonvolatile memory device, and a SRAM device is formed.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended and their equivalents.

What is claimed is:

1. A semiconductor device having a conductive layer comprising:
a semiconductor substrate;
a first interlayer insulating film formed above the semiconductor substrate;
a first conductive layer formed in the first interlayer insulating film;
a second interlayer insulating film formed on the first interlayer insulating film and the first conductive film;
a contact that is formed in the second interlayer insulating film, an one end of the contact being electrically connected to the first conductive layer;
a second conductive layer formed on the second interlayer insulting film and the contact; and
a dummy pattern formed in the first conductive layer and adjacent to the one end of the contact, an upper surface of the dummy pattern reaching a lower surface of the second interlayer insulating film that is formed on the first conductive layer, and the lower surface of the dummy pattern reaching the first interlayer insulating film that is formed under the first conductive layer.

2. The semiconductor device having a conductive layer according to claim 1, the dummy pattern comprises a plurality of insulating films.

3. The semiconductor device having a conductive layer according to claim 1, the dummy pattern comprises a plurality of insulating films, and one of the plurality of the insulating films is located to separate from the others.

4. The semiconductor device having a conductive layer according to claim 1, the dummy pattern comprises a plurality of insulating films, and the plurality of the insulating films are located to surround the one end of the contact.

5. The semiconductor device having a conductive layer according to claim 1, the dummy pattern comprises four insulating films, one of the four insulating films is located to separate from the others, the four insulating films are located so as to surround the one end of the contact, two of the four insulating films are facing each other, and remaining two of the four insulating films are facing each other.

6. The semiconductor device having a conductive layer according to claim 1, the dummy pattern comprises a plurality of insulating films, one of the plurality of the insulating films is located to separate from the others, and the plurality of the insulating films are located so as to surround the one end of the contact within 10 micrometers from the one end of the contact.

7. The semiconductor device having a conductive layer according to claim 1, the dummy pattern is a portion of the first interlayer insulating film that is formed under the first conductive layer.

8. The semiconductor device having a conductive layer according to claim 1, at least one of a dynamic DRAM device, a nonvolatile memory device, and a SRAM device is formed on the semiconductor substrate.

9. A semiconductor device having a conductive layer comprising:
a semiconductor substrate;
a first interlayer insulating film formed above the semiconductor substrate;
a first conductive layer formed in the first interlayer insulating film;
a second interlayer insulating film formed on the first interlayer insulating film and the first conductive layer; and
a contact that is formed in the second interlayer insulating film, an one end of the contact being electrically connected to the first conductive layer;
wherein portions of the first interlayer insulting film are extending into the first conductive layer, the portions of the first interlayer insulting film are adjacent to the end of the contact.

10. The semiconductor device having a conductive layer according to claim 9, one of the portions of the first interlayer insulating film is located to separate from the others.

11. The semiconductor device having a conductive layer according to claim 9, the portions of the first interlayer insulating film are located to surround the one end of the contact.

12. The semiconductor device having a conductive layer according to claim 9, the portions of the first interlayer insulating film comprises four portions, the four portions are located so as to surround the one end of the contact, two of the four portions are facing each other, and remaining two of the four portions are facing each other.

13. The semiconductor device having a conductive layer according to claim 9, the portions of the first interlayer insulating film located so as to surround the one end of the contact within 10 micrometers from the one end of the contact.

14. The semiconductor device having a conductive layer according to claim 9, at least one of a dynamic DRAM device, a nonvolatile memory device, and a SRAM device is formed on the semiconductor substrate.

15. A method for manufacturing a semiconductor device having a conductive layer, comprising:
forming a first interlayer insulting film above a semiconductor substrate;
forming a groove in the first interlayer insulting film by removing a predetermined portion of the first interlayer insulating film in an electrode region at which an electrode is to be formed, and leaving a portion other than the predetermined portion of the first interlayer insulating film in the electrode region;
forming a conductive layer in the groove;
forming a second interlayer insulating film on the first interlayer insulating film and the conductive layer; and
forming a contact in the second interlayer insulating film so as to reach an upper surface of the conductive layer, the upper surface of the conductive layer being adjacent to the portion other than the predetermined portion of the first interlayer insulating film.

16. The semiconductor device having a conductive layer according to claim 15, a step of the forming a conductive layer comprises; forming a barrier metal layer in the groove, and forming a cupper layer in the groove on the barrier metal layer.

17. The semiconductor device having a conductive layer according to claim 16, a step of the forming the conductive layer is a step of forming a cupper plating layer by a plating method.

18. The semiconductor device having a conductive layer according to claim 15, wherein, at a step of the forming the groove, the portion other than the predetermined portion of the first interlayer insulating film is located so as to surround a region at which the contact is to be formed.

19. The semiconductor device having a conductive layer according to claim 15, wherein, at a step of the forming the groove, the portion other than the predetermined portion of the first interlayer insulating film comprises a plurality of dummy patterns, the plurality of the dummy patterns being separated from each other.

20. The semiconductor device having a conductive layer according to claim 15, further comprising; forming at least one of a dynamic DRAM device, a nonvolatile memory device, and a SRAM device is formed on the semiconductor substrate.
